(19) United States
(12) Patent Application Publication
(10) Pub. No.: US 2005/0282975 A1
(43) Pub. Date: Dec. 22, 2005

(54) Silicone epoxy formulations

(75) Inventors: Deborah Ann Haitko, Schenectady, NY (US); Slawomir Rubinsztajn, Niskayuna, NY (US)

Correspondence Address: Scott A. McCollister, Esq.;Fay, Sharpe, Fagan, Minnich & McKee, LLP, Seventh Floor, 1100 Superior Avenue, Cleveland, OH, 44114-2518, US

(73) Assignee: GELcore LLC.

(21) Appl. No.: 10/873,699

(22) Filed: Jun. 22, 2004

(51) Int. Cl. C08L 63/00; C08L 83/00; H01L 21/56; B32B 27/38

(52) U.S. Cl. 525/476; 438/127; 428/413; 428/447

(57) ABSTRACT

An encapsulant composition is provided. The composition includes an epoxy composition including at least a silicone epoxy of the general formula:
MₐM′_{b}D_{c}D′_{d}TₑT′_{f}Q_{g}
wherein a, b, c, d, e, f, and g are independently integers of zero or above, and wherein the sum of b, d, and f is one or greater; M is R¹₃SiO_{1/2}; M′ is (Z)R²₂SiO_{1/2}; D is R³₂SiO_{2/2}; D′ is (Z)R⁴SiO_{2/2}; T is R⁵SiO_{3/2}; and T′ is (Z)SiO_{3/2}; Q is SiO_{4/2} and R¹, R², R³, R⁴, R⁵ are independently selected from the group consisting of H, C₁₋₂₂ alkyl, C₁₋₂₂ alkoxy, C₂₋₂₂ alkenyl, C₆₋₁₄ aryl, C₆₋₂₂ alkyl substituted aryl, C₆₋₂₂ arylalkyl, aminoalkyls, and mixtures thereof; and Z, independently at each occurrence, is an organic radical containing an epoxy group, a curing agent, and a filler. The composition is substantially free of Pt.

### BACKGROUND OF THE INVENTION

This invention relates to light emitting devices including a light emitting diode in combination with a phosphor material. Light emitting diodes (LEDs) are well-known solid-state devices that can generate light having a peak wavelength in a specific region of the visible spectrum. Early LEDs emitted light having a peak wavelength in the red region of the light spectrum, and were often based on aluminum, indium, gallium and phosphorus semiconducting materials. More recently, LEDs based on Group III-nitride where the Group III element can be any combination of Ga, In, Al, B, and Ti have been developed that can emit light having a peak wavelength in the green, blue and ultraviolet regions of the spectrum. The present invention relates to an eqoxy-based encapsulant formulation for lighting devices. As one example, the present invention relates to an encapsulant formulation for light emitting diodes.

An epoxy for this type of application should be homogenous, flexible, optically transparent, and free of residual catalytic material. The epoxies must also be able to withstand thermal shock testing. Current epoxies useful in encapsulant formulations may withstand thermal shock testing, but fall short in terms of optical transparency over extended use. Moreover, these formulations may degrade after extended use, or can develop cracks of peeling of the binder from the substrate of the lighting device.

It would therefore be desirable to develop an encapsulant material that is able to withstand thermal shock testing while maintaining optical transparency over a period of extended use. Additionally, improved flexibility in an encapsulant would lead to reduced stress in the device due to the coefficient of thermal expansion between the inorganic chip and packaging and an organic encapsulant.

### SUMMARY OF THE INVENTION

According to one aspect of the invention, an encapsulant composition is provided. The composition includes an epoxy composition including at least a silicone epoxy of the general formula:
MₐM′_{b}D_{c}D′_{d}TₑT′_{f}Q_{g}
wherein a, b, c, d, e, f, and g are independently integers of zero or above, and wherein the sum of b, d, and f is one or greater; M is R¹₃SiO_{1/2}; M′ is (Z)R²₂SiO_{1/2}; D is R³₂SiO_{2/2}; D′ is (Z)R⁴SiO_{2/2}; T is R⁵SiO_{3/2}; and T is (Z)SiO_{3/2}; Q is SiO_{4/2} and R¹, R², R³, R⁴, R⁵ are independently selected from the group consisting of H, C₁₋₂₂ alkyl, C₁₋₂₂ alkoxy, C₂₋₂₂ alkenyl, C₆₋₁₄ aryl, C₆₋₂₂ alkyl substituted aryl, C₆₋₂₂ arylalkyl, aminoalkyls, and mixtures thereof; and Z, independently at each occurrence, is an organic radical containing an epoxy group, a curing agent, and a filler. The encapsulant composition is substantially free of Pt.

In another embodiment, a method for forming an encapsulant composition is provided. The method includes the step of mixing together an epoxy composition including at least a silicone epoxy of the general formula:
MₐM′_{b}D_{c}D′_{d}TₑT′_{f}Q_{g}
wherein a, b, c, d, e, f, and g are independently integers of zero or above, and wherein the sum of b, d, and f is one or greater; M is R¹₃SiO_{1/2}; M′ is (Z)R²₂SiO_{1/2}; D is R³₂SiO_{2/2}; D′ is (Z)R⁴SiO_{2/2}; T is R⁵SiO_{3/2}; and T′ is (Z)SiO_{3/2}; Q is SiO_{4/2} and R¹, R², R³, R⁴, R⁵ are independently selected from the group consisting of H, C₁₋₂₂ alkyl, C₁₋₂₂ alkoxy, C₂₋₂₂ alkenyl, C₆₋₁₄ aryl, C₆₋₂₂ alkyl substituted aryl, C₆₋₂₂ arylalkyl, aminoalkyls, and mixtures thereof; and Z, independently at each occurrence, is an organic radical containing an epoxy group and being substantially free of Pt, a curing agent, and a filler.

In a third embodiment, an electronic chip package is provided. The package includes an encapsulant composition comprised of an epoxy composition including at least 1,3-bis(1,2-epoxy-4-cyclohexylethyl)-1,1,3,3-tetramethyl disiloxane and being substantially free of Pt, a curing agent, and a filler; an electronic chip; and a phosphor.

### BRIEF DESCRIPTION OF THE DRAWINGS

FIG. 1 is a schematic sectional view of a lamp employing the encapsulant material of the present invention.

### DETAILED DESCRIPTION OF THE INVENTION

An epoxy based composition has been developed for various applications. One particular use is for encapsulating high density interconnected multichip modules. The epoxy resin composition of the present invention preferably comprises an epoxy resin, a curing agent, a non-conductive carbon, and an inorganic filler. The resin is preferably suitable for use as an encapsulant material in lighting devices.

Preferred resins include materials of the general formula of silicone-epoxy resins having the formula:
MₐM′_{b}D_{c}D′_{d}TₑT′_{f}Q_{g}
where the subscripts a, b, c, d, e, f and g are zero or a positive integer, subject to the limitation that the sum of the subscripts b, d and f is one or greater; where M has the formula:
R¹₃SiO_{1/2},
M′ has the formula:
(Z)R²₂SiO_{1/2},
D has the formula:
R³₂SiO_{2/2},
D′ has the formula:
(Z)R⁴SiO_{2/2},
T has the formula:
R⁵SiO_{3/2},
T′ has the formula:
(Z)SiO_{3/2},
and Q has the formula SiO_{4/2}, where each R¹, R², R³, R⁴, R⁵ is independently at each occurrence a hydrogen atom, C₁₋₂₂ alkyl, C₁₋₂₂ alkoxy, C₂₋₂₂ alkenyl, C₆₋₁₄ aryl, C₆₋₂₂ alkyl-substituted aryl, C₆₋₂₂ arylalkyl, and mixtures thereof, which groups may be halogenated, for example, fluorinated to contain fluorocarbons such as C₁₋₂₂ fluoroalkyl, or may contain amino groups to form aminoalkyls, for example aminopropyl or aminoethylaminopropyl, or may contain polyether units of the formula (CH₂CHR⁶O)ₖ where R⁶ is CH₃ or H and k is in a range between about 4 and 20; and Z, independently at each occurrence, represents organic radicals containing an epoxy group. The term “alkyl” as used in various embodiments of the present invention is intended to designate normal alkyl, branched alkyl, aralkyl, and cycloalkyl radicals. Normal and branched alkyl radicals are preferably those containing in a range between about 1 and about 12 carbon atoms, and include as illustrative non-limiting examples methyl, ethyl, propyl, isopropyl, butyl, tertiary-butyl, pentyl, neopentyl, and hexyl. Cycloalkyl radicals represented in the present invention are preferably those containing in a range between about 4 and about 12 ring carbon atoms. Some illustrative non-limiting examples of these cycloalkyl radicals include cyclobutyl, cyclopentyl, cyclohexyl, methylcyclohexyl, and cycloheptyl. Preferred aralkyl radicals are those containing in a range between about 7 and about 14 carbon atoms; these include, but are not limited to, benzyl, phenylbutyl, phenylpropyl, and phenylethyl.

Aryl radicals used in the various embodiments of the present invention are preferably those containing in a range between about 6 and about 14 ring carbon atoms. Some illustrative non-limiting examples of these aryl radicals include phenyl, biphenyl, and naphthyl. An illustrative non-limiting example of a suitable halogenated moiety is trifluoropropyl. Combinations of epoxy monomers and oligomers may also be used in the present invention.

An especially preferred epoxy resin is 1,3-bis(1,2-epoxy-4-cyclohexylethyl)-1,1,3,3-tetramethyl disiloxane (MeMe). MeMe is known for use in light emitting technology. Previous methods for synthesizing MeMe have, however, resulted in residual Pt catalytic material remaining in the encapsulant composition. The presence of residual Pt results in shorter shelf life and yellowing of the material over time.

In the present invention, the MeMe composition is synthesized according to a novel process, resulting in an MeMe composition that is substantially free, or free, of residual Pt catalytic material. MeMe is preferably formed via a Pt-catalyzed hydrosilation reaction between 4-vinyl-cyclohexene oxide and tetramethyl disiloxane. Preferred catalyst systems include 0.5% by weight of platinum on alumina, platinum on carbon, platinum on silica. There are several examples of effective heterogeneous catalysts available as pellets. Catalyst availability in pellet form provides ease of removal once the reaction is complete. Since the catalyst is insoluble in the reaction, unlike the previously disclosed homogeneous systems such as cis-bis-triphenylphosphine platinum dichloride and Karsted's catalyst, for example, the removal of the catalyst is simple and effective without damaging the product. Moreover, the Pt catalyst can be recycled and reused after recovery from the synthesis.

The resulting material preferably has an optical clarity of greater than about 65%, more preferably greater than about 75%, and most preferably greater than about 85% at 400 nm. A curing agent is preferably added to the present composition. The curing agent is preferably a multifunctional organic compound capable of reacting with the epoxy functionalities located within the composition. Suitable curing agents include resins obtained by the condensation or co-condensation of phenols (e.g. phenol, cresol, resorcin, catechol, bisphenol A and bisphenol F) and/or naphthols (e.g., α-naphthlol, β-naphthol, and dihydroxynaphthalene) with aldehydes such as formaldehyde in the presence of an acid catlyst; aralkyl type phenolic resins (e.g., phenol-aralkyl resins and naphthol-aralkyl resins); and mixtures thereof. Other preferred curing agents include amines, amides, phenols, thiols, carboxylic acids, carboxylic anhydrides, and mixtures thereof. The most preferred curing agents are anhydrides, and examples of exemplary curing agents include cis-1,2-cyclo hexane dicarboxylic anhydride, methylhexohydropthalic anhydride, hexahydrophthalic anhydride, and mixtures thereof.

The curing agent is preferably mixed in such an amount that the equivalent weight of phenolic hydroxyl groups is from about 0.5 to about 1.5 equivalent weight, and more preferably from about 0.8 to about 1.2 equivalent weight, the epoxy resin may cure insufficiently to tend to make the cured product have poor heat resistance, moisture resistance, and electrical properties. If it is more than about 1.5 equivalent weight, the curing agent constituent is present in excess, so that the phenolic hydroxyl groups may remain in a large quantity in the cured-product resin. This could result in poor electrical properties and moisture resistance.

A curing accelerator may also be preferably mixed with the resin of the present invention to accelerate the etherification reaction of epoxy groups with phenolic hydroxyl groups. Preferred curing accelerators include tertiary amines, such as 1,8-diazabicyclo[5.4.0]undecene-7, 1,5-diazabicyclo[5.4.0]nonene, 5,6-dibutylamino-1,8-diazabicyclo[5.4.0]undecene-7, benzyldimethylamine, triethanolamine, dimethylaminoethanol and tris(dimethylaminomethyl)phenol; imidazoles, such as 2-methylimidazole, 2-phenylimidazole, and 2-phenyl-4-methylimidazole; organophosphines, such as tributylphosphine, methyldiphenylphosphine, triphenylphosphine, diphenylphosphine, and phenylphosphine; phophorus coumounds having intramolecular polarization, including any of the above organophosphines to which a compound having a π-bond such as maleic anhydride, benzoquinone, or diazophenylmethane has been added; tetraphenyl phophonium tetraphenylborate, triphenylphosphine tetraphenylborate, 2-ethyl-4-methylimidazole tetraphenylbborate, alkyl sulfonium salts, N-methyltetraphenylphosphonium tetraphenylborate, triphenylphosphonium triphenylborate, and mixtures thereof.

The curing accelerator may preferably be mixed in an amount of from about 0.01 to 5 parts by weight, and more preferably from about 0.1 to about 3 parts by weight, based on 100 parts by weight of the epoxy resin.

A filler, such as a nano silica or other material that will not retard optical transparency may also be included in the formulation.

An additional filler, such as an inorganic filler, may also be included in the composition of the present invention. A filler may be useful for reducing moisture absorption and improving strength of the resultant encapsulant composition. Fillers commonly used in the art may be utilized in the present composition. Especially preferred fillers include powders of fused silica, crystalline silica, alumina, zircon, calcium silicate, calcium carbonate, silicon carbide, boron nitride, beryllia and zirconia, or beads of any of these made spherical; single-crystal fibers of potassium titante, silicon carbide, silicon nitride and alumina, or glass fibers; inorganic fillers having a flame-retardant effect, such as aluminum hydroxide and zinc borate, and mixtures thereof. Of these, fused silica may reduce the coefficient of linear expansion, and alumina may improve the thermal conductivity of the resultant composition. Spherical particles may improve flowability and mold wear resistance at the time of molding.

The filler may be mixed in an amount of from about 70 to 98% by weight, and more preferably between about 75 and 95% by weight, based on the total weight of the encapsulant epoxy resin composition.

A coupling agent may also be added to the present invention. The inclusion of a coupling agent may improve the affinity of the filler for the resin constituent. Coupling agents commonly used in the art may be selected. Preferred coupling agents include silane type coupling agents such as vinyltrichlorosilane, vinyltriethoxysilane, vinyltris(β-methoxyethyoxy) silane, γ-methacryloxypropyltrimethoxysilane, β-(3,4-epoxydicyclohexyl)ethyltrimethoxysilane, γ-glycidoxypropyltrimethoxysilane, vinlytriacetoxysilane, γ-mercaptopropyltirmethoxysilane, γ-aminopropyltriethoxysilane, γ-[bis-(β-hydroxyethyl)]aminopropyltriethoxysilane, N-β-(aminoethyl)-γ-aminopropyltrimethoxysilane, γ-(β-aminoethyl)aminopropyldimethoxymethylsilane, N-(trimethoxysiliylpropyl)ethylenediamine, N-(dimethoxysilylisopropyl)ethylenediamine, methyltrimethoxysilane, methyltriethoxysilane, n-β-(N-vinylbenzylaminoethyl)-γ-aminopropyltrimethoxysilane, γ-chloropropyltrimethoxysilane, hexamethyldisilane, γ-anilinopropyltrimethoxysilaen, vinyltrimethoxysilane and γ-mercaptopropylmethyldimethoxysilane; titanate type coupling agents such as isopropyltriisosteroyl titanate, isopropyltris(diocylpyrophosphate) titanate, isoprpyltri(N-aminoethyl-aminoethyl)titanate, tetraoctylbis(ditridecyl phosphite) titanate, tetra(2,2-diallyloxymethyl-1-butyl)bis(ditridecyl)phophite titanate, bis(dioctyl pyrophosphate) oxyacetate titanate, bis(dioctyl pyrophosphate) ethylene titante, isopropyltrioctanoyl titante, isoprpyldimethacrylisostearoyl titante, isopropyltridodecylbenzenesulfonyltitanate, isopropylisostearoyldiacryl titanate, isopropyltri(dioctyl phosphate) titanate, isopropyltricumylphenyl titanate and tetraisoprpylbis (dioctyl phosphite) titanate; and mixtures thereof.

Bonding enhancers are preferably added to the present adhesive composition to improve the interaction of the components within the composition. Preferred bonding enhancers are multifunctional epoxies. More preferably, the bonding enhancers are epoxies with at least about 3 epoxy moieties within the compound. Exemplary bonding enhancers include N,N′-diglycidyl-p-aminophenyl-glycidyl ether, triglycidyl p-aminophenol derived resins, 1,3,5-triglycidyl isocyanurate, tetraglycidylmethylenedianiline, and glycidyl ether of novolac epoxies. The bonding enhancers are preferably added to the present composition in an amount between about 3 and 30% by weight of the total composition, more preferably between about 9 and 26 wt %.

Hardeners may also be added to the present adhesive composition to improve the curing reaction. Preferred hardeners are amine hardeners. Exemplary amine hardeners include isophoronediamine, triethylenetetraamine, diethylenetriamine, aminoethylpiperazine, 1,2- and 1,3-diaminopropane, 2,2-dimethylpropylenediamine, 1,4-diaminobutane, 1,6-diaminohexane, 1,7-diaminoheptane, 1,8-diaminooctane, 1,9-diaminononae, 1,12-diaminododecane, 4-azaheptamethylenediamine, N,N′-bis(3-aminopropyl)butane-1,4-diamine, cyclohexanediamine, dicyandiamine, diamide diphenylmethane, diamide diphenylsulfonic acid (amine adduct), 4,4′-methylenedianiline, diethyltoluenediamine, m-phenylene diamine, melamine formaldehyde, tetraethylenepentamine, 3-diethylaminopropylamine, 3,3′-iminobispropylamine, 2,4-bis(p-aminobenzyl)aniline, tetraethylenepentamine, 3-diethylaminopropylamine, 2,2,4- and 2,4,4-trimethylhexamethylenediamine, 1,2- and 1,3-diaminocyclohexane, 1,4-diamino-3,6-diethylcyclohexane, 1,2-diamino-4-ethylcyclohexane, 1,4-diamino-3,6-diethylcyclohexane, 1-cyclohexyl-3,4-dimino-cyclohexane, 4,4′-dimiondicyclohexylmethane, 4,4′-diaminodicyclohexylpropane, 2,2-bis(4-aminocyclohexyl)propane, 3,3′-dimethyl-4,4′diamiondicyclohexylmethane, 3-amino-1-cyclohexaneaminopropane, 1,3- and 1,4-bis(aminomethyl)cyclohexane, m- and p-xylylendiamine, and mixtures thereof. A particularly preferred amine hardeners is melamine formaldehyde. The hardening agent is preferably added to the present adhesive composition in an amount between about 4 and 20 wt % of the total composition, more preferably between about 6 and 15 wt. %.

Flexibilizing components are also preferably added to the present adhesive composition to better function as a chip-on-flex adhesive. Preferred flexibilizers contain substantially no carbon. Low carbon content flexibilizers are preferred to limit the later formation of soot if the applied composition is laser ablated. Suitable flexibilizers include silicone polymer additives, including fumed and unfumed silica, alumina polymer additives, including fumed and unfumed alumina, polysulfide rubbers, and mixtures thereof. Flexibilizers typically used in polyurethane systems are also suitable. Flexibilizers are preferably added to the present adhesive composition in an amount between about 3 and 20 wt % of the total composition, more preferably between about 5 and 10 wt %.

Additional additives known in the art may also be added to the present epoxy composition. For example, a release agent such as a higher fatty acid (e.g., carnauba wax or a polyethylene type wax), a modifier such as silcone oil or silicone rubber, an ion trapper such as hydrotalcite or antimony-bismuth and mixtures thereof may optionally be mixed as other additives.

In the encapsulant epoxy resin composition of the present invention, at least one colorant may further be used in combination as long as they are within the scope where the effect of the present invention is achievable; the colorants being exemplified by azine dyes, anthraquinone dyes, disazo dyes, diiminium dyes, aminium duyes, diimonium dyes, Cr complexes, Fe complexes, Co complexes, Ni complexes, Fe, Cu, Ni, and the like metal compounds, Al, Mg, Fe, and the like metal oxides, mica, near infrared absorbers, phthalocyanine pigments, phthalocyanine dyes, carbon black, and mixtures thereof. In particular, phthalocyanine dyes may preferably be used in combination in view of laser markability, flowability, and curability.

The encapsulant epoxy resin composition of the present invention may be prepared by methods known in the art as long as the constituent materials can uniformly be dispersed and mixed. As a commonly available method, a method may be sued in which stated amounts of the constituent materials are thoroughly mixed by means of a mixer and thereafter melt-kneaded by means of a heat roller or extruder, followed by cooling and pulverization. It may be preferred to mold the product thus obtained into tablets in such a size and weight that may suit to molding conditions, so as to be usable with ease.

The curing reaction of the present composition is preferably carried out by the addition of a catalyst. Preferred catalysts are substances that contain an unshared pair of electrons in an outer orbital, including Lewis Bases such as tertiary amines, imidazoles, and imidazolines. Exemplary catalysts include 2-ethyl-4-methyl-imidazole, N-(3-aminopropyl) imidazole, 2-phenyl-2-imidazoline, and mixtures thereof. The selected catalysts are added to the present composition in an amount between about 0.05 and 1.0 wt % of the total composition, more preferably between about 0.1 and 0.3 wt %.

A tackifier may be added to the present composition. The tackifier can be added to improve thermal resistance. Preferred tackifiers are thermoset resins such as phenolics and melamines. Especially preferred tackifiers are carboxyl terminated compounds. Exemplary tackifying agents include melamine formaldehyles, urea formaldehydes, phenol formaldehydes, epoxidized ortho cresol novolacs, and mixtures thereof. Tackifiers can be added to the present composition in an amount between about 5 and 20 wt % of the total composition, more preferably between about 6 and 15 wt %.

While the present invention is suited for use with any type of light emitting device including those emitting red and yellow regions, it may be particularly beneficially when used with LEDs emitting in the green blue and/or UV regions where phosphor conversion is usually employed. Representative examples of green blue and/or UV emitting LEDs are those referred to as gallium nitride based.

One exemplary type of LED design provided for demonstration purposes only is the following: the materials made of AlₓGa_{y}In(_{1-x-y})N where both X and Y is between 0 and 1(0≦X≦1, 0≦Y≦1) and wherein a narrower bandgap GaN-based light-emitting structure is sandwiched between single or multiple layers of wider bandgap GaN-based structures with different conductivity types on different sides of the light-emitting structure.

Of course, the present invention is not limited thereto. Moreover, the present invention is believed beneficial with LEDs of any construction and, particularly those where a relatively thick substrate is utilized. Accordingly, the present invention can function with radiation of any wavelength provided phosphor compatibility exists. Similarly, the present invention is compatible with double heterostructure, multiple quantum well, single active layer, and all other types of LED designs. For example, the LED may contain at least one semiconductor layer based on GaN, ZnSe or SiC semiconductors. The LED may also contain one or more quantum wells in the active region, if desired. Typically, the LED active region may comprise a p-n junction comprising GaN, AlGaN and/or InGaN semiconductor layers. The p-n junction may be separated by a thin undoped InGaN layer or by one or more InGaN quantum wells.

The present invention can operate with any suitable phosphor material or combinations of phosphor materials. Moreover, provided that a phosphor which is compatible with the selected LED is used, the present invention can improve the device performance. Importantly, this means that no requirement exists in the invention with respect to the wavelength generated by the LED, the wavelength the phosphor excites or re-emits, or at the overall wavelength of light emitted by the light emitting device. Nonetheless, several exemplary phosphor systems are depicted below to facilitate an understanding of the invention.

Conventionally, a blue LED is an InGaN single quantum well LED and the phosphor is a cerium doped yttrium aluminum garnet (“YAG:Ce”), Y3Al5O12:Ce3⁺. The blue light emitted by the LED is transmitted through the phosphor and is mixed with the yellow light emitted by the phosphor. The viewer perceives the mixture of blue and yellow light as white light. One alternative phosphor is a TAG:Ce wherein terbium is substituted for yttrium. Other typical white light illumination systems include a light emitting diode having a peak emission wavelength between 360 and 420 nm, a first APO:Eu²⁺, Mn²⁺ phosphor, where A comprises at least one of Sr, Ca, Ba or Mg, and a second phosphor selected from at least one of:
a) A₄D₁₄O₂₅:Eu²⁺, where A comprises at least one of Sr, Ca, Ba or Mg, and D comprises at least one of Al or Ga;
b) 2AO* 0.84P₂O₅* 0.16B2O3):Eu²⁺, where A comprises at least one of Sr, Ca, Ba or Mg;
c) AD₈O₁₃:Eu²⁺, where A comprises at least one of Sr, Ca, Ba or Mg and D comprises at least one of Al or Ga;
d) A₁₀(PO₄)6Cl₂:Eu²⁺, where A comprises at least one of Sr, Ca, Ba or Mg; or
e) A₂Si₃O₈* 2AC1₂:Eu²⁺, where A comprises at least one of Sr, Ca, Ba or Mg.

Accordingly, the phosphor system may be a blend of materials. For example, a white light illumination system can comprise blends of a first phosphor powder having a peak emission wavelength of about 570 to about 620 nm and a second phosphor powder having a peak emission wavelength of about 480 to about 500 nm to form a phosphor powder mixture adjacent the LED.

Exemplary polymeric fillers include silicones, several examples of which are available from GE-Toshiba Silicones, which can be used interchangeably as the transparent fill layer or as the phosphor dispersion layer. In addition, it is contemplated that the dispersion layer can be phosphor suspension a volatile organic solution such as a low molecular weight alcohol. Advantageously, the filler layer, the phosphor containing layer and the optic lens element can be formed/assembled according to any techniques known to the skilled artisan.

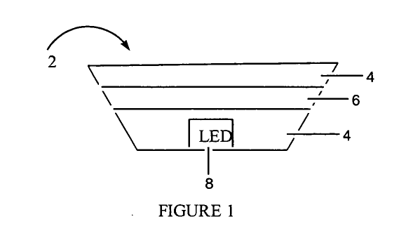

With reference to FIG. 1, a schematic view of a light source 2 is shown. The encapsulant material 4 is located adjacent to a phosphor layer 6. The phosphor layer 6 is excited by, for example, a UV/blue light emitted by the LED 8 and converts that light to visible white light.

Notwithstanding the depicted embodiment, the skilled artisan will recognize that any LED device configuration may be improved by the inclusion of the present inventive encapsulant composition. The embodiment specifically described herein is meant to be illustrative only and should not be construed in any limiting sense.

In the following, the present invention will be described in more detail with reference to non-limiting examples. These examples are for the purposes of illustration only and should not be construed in any limiting sense.

### EXAMPLES

305 grams of vinylcyclohexene-1,2-diepoxide and 183 gm of toluene were added to a 2 liter round neck flask equipped with thermometer, condenser and addition funnel. One to eight pellets of 0.5% by weight of platinum on alumina were also added and the mixture heated to reflux at approximately 130° C. At this time 150 gms of tetramethyldisiloxane were slowly added to control the reflux and exothermic reaction. Once all the siloxane was added the reaction was further heated no higher than 140° C. for one hour. The reaction was then cooled to room temperature and transferred to a 1 liter one neck flask prior to solvent removal. The reaction mixture could easily be decanted into the one neck flask leaving the platinum containing pellets behind. Solvents and excess vinylcyclohexene-1,2-diepoxide were removed in vacuo.

Silicone epoxy monomers made by heterogenous catalysis, such as MeMe for example, were blended with various antioxidants and stabilizers prior to reaction with a hydrogenated phthalic anhydride hardener and catalyst. The resulting epoxide/anhydride mixture was cured in two steps: one half hour at 100° C. and three hours cure at 150° C. The materials cured with retention of optical transparency exhibiting transmission at 400 nm of 88%. The epoxide mixtures could also be cured without addition of the hardener using a transparent catalyst such as 0.01-0.05 wt % of the thermally curing catalyst, 3-methyl-2-butenyltetramethylene sulfonium hexafluoroantimonate. The catalyst and formulation were blended at room temperature for approximately one-half hour after which time the formulation was degassed at room temperature for 20 minutes. Cure of the transparent and clear blended composition in disk form was accomplished in two stages, first curing at 30 minutes at 90° C. for approximately one-half hour and then final cure was achieved after a 2 hour cure was performed at 130° C. The molded disk was exposed to UV flux from an argon laser at 406 nanometers (nm) at approximately 300 milliwatts for 24 hours. The decrease in transmission was less than 2% versus initial measurements.

Exposing the cured epoxy formulations to an ultraviolet (UV) flux greater than 0-10 times that emitted from UV or blue LEDs showed material of the present invention exhibited greater than 10% improvement of optical transmission versus typical LED encapsulants such as cycloolefin polymers and copolymers. Optical transmission was measured by utilizing a Macbeth Spectrophotometer.

Although the invention has been described with reference to the exemplary embodiments, various changes and modifications can be made without departing from the scope and spirit of the invention. These modifications are intended to fall within the scope of the invention, as defined by the following claims.

1. An encapsulant composition comprising:
a. an epoxy composition including a silicone epoxy of the general formula:
MₐM′_{b}D_{c}D′_{d}TₑT′_{f}Q_{g}
wherein a, b, c, d, e, f, and g are independently integers of zero or above, and wherein the sum of b, d, and f is one or greater; M is R¹₃SiO_{1/2}; M′ is (Z)R²₂SiO_{1/2}; D is R³₂SiO_{2/2}; D′ is (Z)R⁴SiO_{2/2}; T is R⁵SiO_{3/2}; and T′ is (Z)SiO_{3/2}; Q is SiO_{4/2} and R¹, R², R³, R⁴, R⁵ are independently selected from the group consisting of H, C₁₋₂₂ alkyl, C₁₋₂₂ alkoxy, C₂₋₂₂ alkenyl, C₆₋₁₄ aryl, C₆₋₂₂ alkyl substituted aryl, C₆₋₂₂ arylalkyl, aminoalkyls, and mixtures thereof; and Z, independently at each occurrence, is an organic radical containing an epoxy group,
b. a curing agent,
c. a filler,
d. and wherein said encapsulant composition is substantially free of Pt.

2. The composition of claim 1 wherein said silicone epoxy is 1,3-bis(1,2-epoxy-4-cyclohexylethyl)-1,1,3,3-tetramethyl disiloxane formed by a reaction between 4-vinyl-cyclohexene oxide and tetramethyl disiloxane.

3. The composition of claim 2 wherein said reaction is a hydrosilation reaction.

4. The composition of claim 3 wherein said hydrosilation reaction is Pt-catalyzed, utilizing heterogeneous Pt-pellets.

5. The encapsulation composition of claim 1 wherein said encapsulant composition has an optical clarity greater than about 65% at 400 nm.

6. The composition of claim 1 wherein said curing agent is selected from the group consisting of resins obtained by the condensation or co-condensation of phenols and naphthols with aldehydes, aralkyl phenolic resins, amines, amides, phenols, thiols, carboxylic acids, carboxylic anhydrides, and mixtures thereof.

7. The composition of claim 1 wherein said filler is selected from the group consisting of non-conductive carbon; powders of fused silica, crystalline silica, alumina, zircon, calcium silicate, calcium carbonate, silicon carbide, boron nitride, beryllia, zirconia; single-crystal fibers of potassium titanate, silicon carbide, silicon nitride, alumina; glass fibers; inorganic fillers having a flame retardant effect, and mixtures thereof.

8. The composition of claim 1 further including a coupling agent.

9. The composition of claim 1 wherein said R¹, R², R³, R⁴, and R⁵ may independently be halogenated.

10. A method for forming an encapsulant composition comprising the step of mixing together:
a. an epoxy composition including a silicone epoxy of the general formula:
MₐM′_{b}D_{c}D′_{d}TₑT′_{f}Q_{g}
wherein a, b, c, d, e, f, and g are independently integers of zero or above, and wherein the sum of b, d, and f is one or greater; M is R¹₃SiO_{1/2}; M′ is (Z)R²₂SiO_{1/2}; D is R³₂SiO_{2/2}; D′ is (Z)R⁴SiO_{2/2}; T is R⁵SiO_{3/2}; and T′ is (Z)SiO_{3/2}; Q is SiO_{4/2} and R¹, R², R³, R⁴, R⁵ are independently selected from the group consisting of H, C₁₋₂₂ alkyl, C₁₋₂₂ alkoxy, C₂₋₂₂ alkenyl, C₆₋₁₄ aryl, C₆₋₂₂ alkyl substituted aryl, C₆₋₂₂ arylalkyl, aminoalkyls, and mixtures thereof; and Z, independently at each occurrence, is an organic radical containing an epoxy group, formed in the presence of Pt-pellets and being substantially free of Pt,
b. a curing agent, and
c. a filler.

11. The method of claim 10 wherein said silicone epoxy is 1,3-bis(1,2-epoxy-4-cyclohexylethyl)-1,1,3,3-tetramethyl disiloxane formed by a reaction between 4-vinyl-cyclohexene oxide and tetramethyl disiloxane.

12. The method of claim 11 wherein said reaction is a hydrosilation reaction.

13. The method of claim 12 wherein said hydrosilation reaction is Pt-catalyzed, utilizing heterogeneous Pt-pellets.

14. The method of claim 10 wherein said encapsulant composition has an optical clarity greater than about 65% at 400 nm.

15. The method of claim 10 wherein said curing agent is selected from the group consisting of resins obtained by the condensation or co-condensation of phenols and naphthols with aldehydes, aralkyl phenolic resins, amines, amides, phenols, thiols, carboxylic acids, carboxylic anhydrides, and mixtures thereof.

16. The method of claim 10 wherein said filler is selected from the group consisting of non-conductive carbon; powders of fused silica, crystalline silica, alumina, zircon, calcium silicate,- calcium carbonate, silicon carbide, boron nitride, beryllia, zirconia; single-crystal fibers of potassium titanate, silicon carbide, silicon nitride, alumina; glass fibers; inorganic fillers having a flame retardant effect, and mixtures thereof.

17. The method of claim 10 further including the step of mixing a coupling agent into the composition.

18. The method of claim 10 wherein said R¹, R², R³, R⁴, and R⁵ may be independently halogenated.

19. The method of claim 10 wherein said mixing step is carried out at a temperature below about 100° C.

20. An electronic chip package comprising:
a. an encapsulant composition comprised of an epoxy composition including at least 1,3-bis(1,2-epoxy-4-cyclohexylethyl)-1,1,3,3-tetramethyl disiloxane, a curing agent, and a filler, wherein said encapsulant composition is substantially free of Pt;
b. an electronic chip, and
c. a phosphor.
